(19) United States
(12) Patent Application Publication
(10) Pub. No.: US 2008/0035964 A1
(43) Pub. Date: Feb. 14, 2008

(54) CMOS IMAGE SENSOR

(76) Inventor: Sang-Gi Lee, Gyeongi-do (KR)

Correspondence Address: SHERR & NOURSE, PLLC, 620 HERNDON PARKWAY, SUITE 200, HERNDON, VA, 20170, US

(21) Appl. No.: 11/831,477

(22) Filed: Jul. 31, 2007

(30) Foreign Application Priority Data
Aug. 11, 2006 (KR) 10-2006-0076185

(51) Int. Cl. H01L 31/062; H01L 21/00

(52) U.S. Cl. 257/291; 438/98; 257/E27.118; 257/E21.001

(57) ABSTRACT

Embodiments relate to a CMOS image sensor and a fabricating method thereof. In embodiments, a linear nitride layer formed on a semiconductor substrate may protect a gate oxide layer during a process of removing a silicide barrier layer, and may improve the performance of an CMOS image sensor.

The present invention claims priority under 35 U.S.C. 119 and 35 U.S.C. 365 to Korean Patent Application No. 10-2006-0076185 (filed on Aug. 11, 2006), which is hereby incorporated by reference in its entirety.

### BACKGROUND

CMOS image sensors may be machine vision devices that may convert an optical signal into an electric signal. Such a CMOS image sensor may be divided into a pixel region, which may be responsive to an optical signal, and a periphery region, which may not be responsive to an optical signal.

To maintain high performance of a CMOS image sensor, a silicide process may be required in the fabrication of the CMOS image sensor. It may therefore be necessary to form silicide in the periphery region. This is because silicide of a diode formed in the pixel region may degrade light transmission characteristics and may cause junction leakage of a pixel transistor.

According to a related art method of fabrication, a silicide barrier layer may be removed from the pixel region by an etching process, and a gate oxide layer formed in the pixel region may also be removed. Consequently, a performance of optical diodes may be degraded and a yield of the CMOS image sensors may be reduced.

### SUMMARY

Embodiments relate to a complementary metal oxide semiconductor (CMOS) image sensor, and to a CMOS image sensor, which may protect a gate oxide layer and may improve a performance of the CMOS image sensor. Embodiments relate to a method of fabricating a CMOS image sensor, which may protect a gate oxide layer and may improve a performance of the CMOS image sensor.

According to embodiments, a method for fabricating a CMOS image sensor may include preparing a semiconductor substrate in which a pixel region and a periphery region may be defined and on which a gate electrode may be formed, coating a poly oxide layer over the semiconductor substrate, depositing a linear nitride layer over the resulting structure, forming a silicide barrier layer in the pixel region, forming a silicide layer in the periphery region, and removing the silicide barrier layer formed in the pixel region.

According to embodiments, a CMOS image sensor may include a semiconductor substrate in which a pixel region and a periphery region may be defined and on which a gate electrode may be formed, a gate oxide layer in a pixel region of the semiconductor substrate, a linear nitride layer over the gate oxide layer, and a silicide layer in the periphery region.

### DRAWINGS

FIGS. 1a to 1h are cross-sectional drawings illustrating a CMOS image sensor and a method for fabricating a CMOS image sensor according to embodiments.

### DETAILED DESCRIPTION

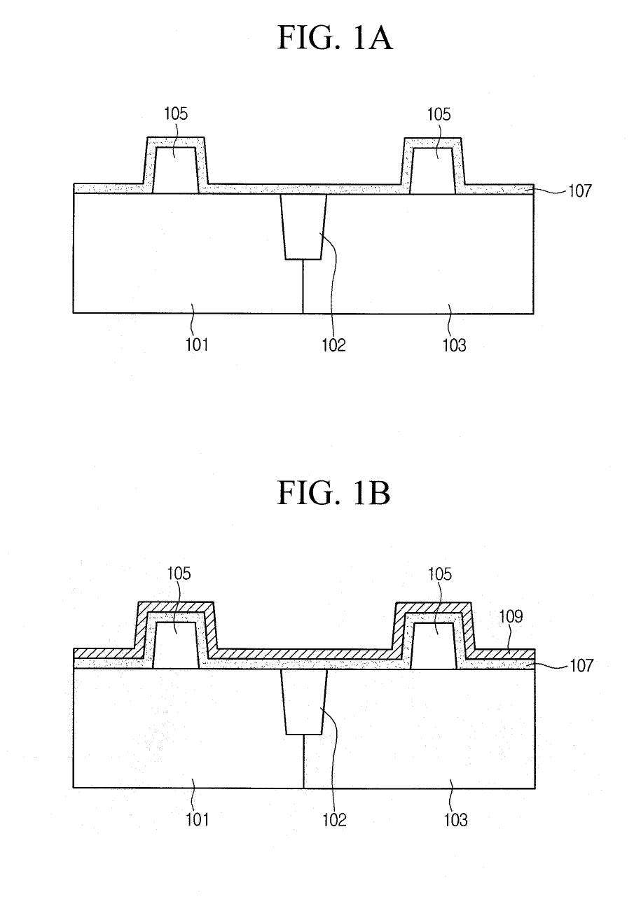

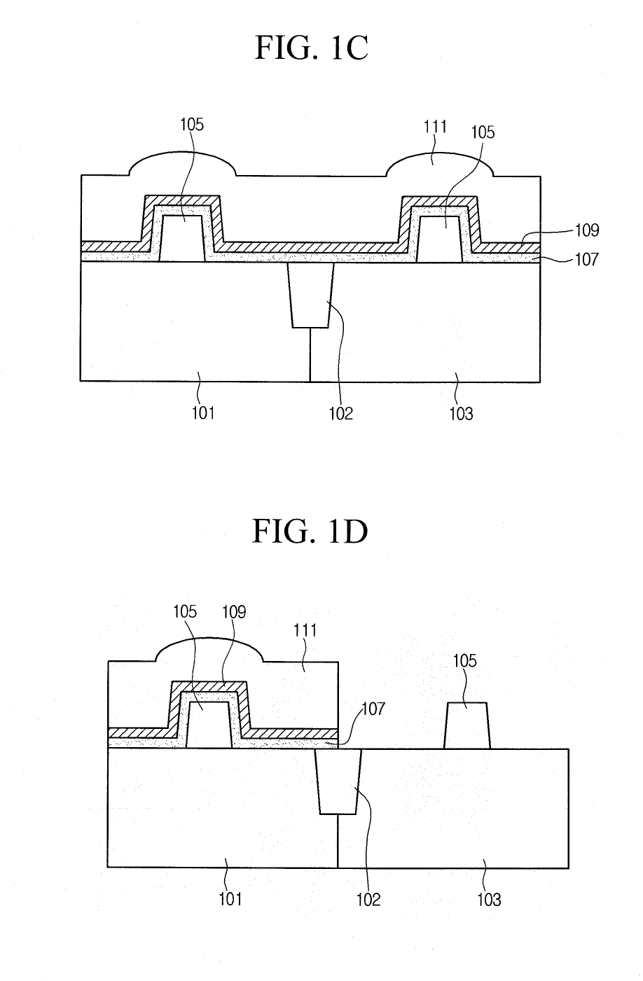

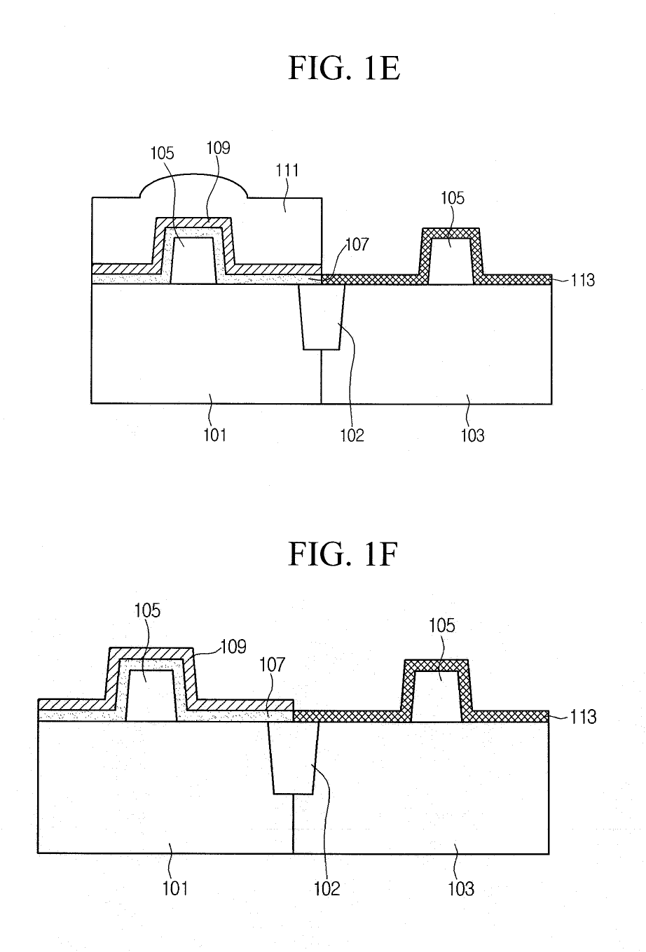

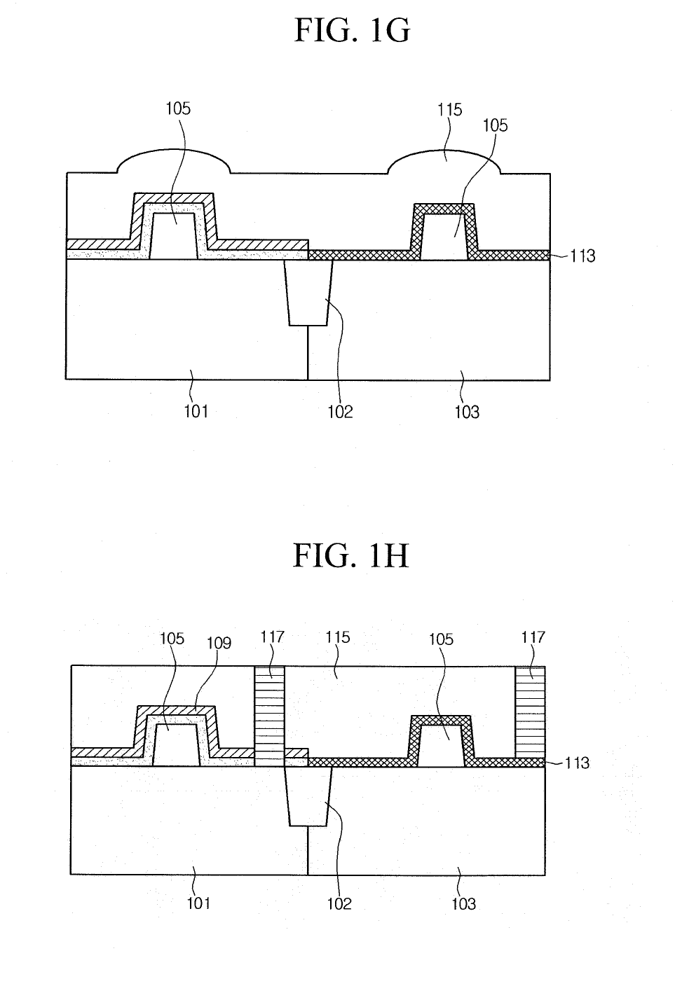

Referring to FIG. 1a, a semiconductor substrate may be divided into pixel region 101 and periphery region 103. Gate electrode 105 may be formed on the semiconductor substrate, and poly oxide layer 107 may be formed over the resulting structure. Gate electrode 105 may include a gate oxide layer and a spacer. A source/drain region and a lightly doped drain (LDD) structure may be formed in the semiconductor substrate. In FIGS. 1a to 1h, these components are not illustrated for clarity. Isolation layer 102 may also be provided.

Referring to FIG. 1b, linear nitride layer 109 may be deposited over the resulting structure. Linear nitride layer 109 may have a thickness ranging from approximately 300 Å to approximately 500 Å.

When a thickness of linear nitride layer 109 is less than 300 Å, poly oxide 107 may not be effectively protected during a subsequent process of removing a barrier layer. In embodiments, if the thickness of linear nitride layer 109 is greater than 500 Å, deformation due to stress may easily occur therein.

Referring to FIG. 1c, silicide barrier layer 111 may be coated on the semiconductor substrate over linear nitride layer 109. Silicide barrier layer 111 may be formed of an oxide material, for example, plasma-enhanced tetra-ethyl-ortho-silicate (PETEOS).

Referring to FIG. 1d, silicide barrier layer 111, linear nitride layer 109, and poly oxide layer 107, which may correspond to periphery region 103, may be etched by a photolithography process.

Referring to FIG. 1e, silicide layer 113 may be deposited in periphery region 103. The silicide depositing process may include sputtering and annealing a metal material, for example, cobalt (Co). Due to silicide barrier layer 111, silicide may not be formed in pixel region 101.

Silicide layer 113 may be formed in periphery region 103 and may prevent transmission of light through periphery region 103 and current leakage.

Referring to FIG. 1f, silicide barrier layer 111 may be removed. A reason for this may be that silicide barrier layer 111 may lower a performance of the image sensor because it may block and reflect light irradiated onto the pixel region. In embodiments, Silicide barrier layer 111 may be removed by a photolithography process.

Linear nitride layer 109 may have been formed above gate electrode 105. Hence, poly oxide layer 107 formed under linear nitride layer 109 may not be exposed to the etching process of removing silicide barrier layer 111. Poly oxide layer 107 may thus be protected by linear nitride layer 109.

Therefore, linear nitride layer 109 may prevent poly oxide layer 107 from being damaged by the etching process.

Referring to FIG. 1g, insulating layer 115 may be formed over the resulting structure. Insulating layer 115 may be formed of phosphorus silicate glass (PSG).

Referring to FIG. 1h, insulating layer 115 may be planarized and contact 117 may be formed. In embodiments, the planarization of insulating layer 115 may be performed by a chemical mechanical polishing (CMP) process.

The forming of contact 117 may include forming a hole in insulating layer 115 and plugging the hole with a metal (e.g., tungsten). The hole for contact 117 may be formed by a photolithography process.

According to embodiments, the linear nitride layer may protect the gate oxide layer during the silicide process, and may thereby improve a performance and yield of the CMOS image sensors.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
preparing a semiconductor substrate having a pixel region and a periphery region and on which a gate electrode is formed;
forming a silicide barrier layer over only the pixel region;
forming a silicide layer over only the periphery region; and
removing the silicide barrier layer formed over the pixel region.

2. The method of claim 1, further comprising:
coating a poly oxide layer over the semiconductor substrate before forming the silicide barrier layer over the pixel region; and
depositing a linear nitride layer over the poly oxide layer before forming the silicide barrier layer over the pixel region.

3. The method of claim 2, wherein the linear nitride layer has a thickness ranging from approximately 300 Å to approximately 500 Å.

4. The method of claim 2, wherein the silicide barrier layer comprises plasma-enhanced tetra-ethyl-ortho-silicate (PETEOS).

5. The method of claim 2, further comprising:
coating an insulating layer over the semiconductor substrate;
selectively etching the insulating layer to form a hole; and
plugging the hole with metal to form a contact.

6. The method of claim 5, wherein the insulating layer comprises phosphorus silicate glass (PSG).

7. The method of claim 5, further comprising forming metal contacts in each of the pixel region and the periphery region.

8. A device, comprising:
a semiconductor substrate having a pixel region and a periphery region;
a gate electrode in each of the pixel region and periphery region;
a gate oxide layer over only a pixel region of the semiconductor substrate;
a linear nitride layer over only the gate oxide layer; and
a silicide layer over only the periphery region of the semiconductor substrate.

9. The device of claim 8, wherein the linear nitride layer has a thickness ranging from approximately 300 Å to approximately 500 Å.

10. The device of claim 8, further comprising:
an insulating layer over the semiconductor substrate; and
a contact in the insulating layer, the contact being formed of a metal plug.

11. The device of claim 10, further comprising contacts in the insulating layer over each of the pixel region and periphery region.

12. The device of claim 8, wherein the insulating layer comprises phosphorus silicate glass (PSG).

13. The device of claim 8, wherein a silicide barrier layer is temporarily formed over only the pixel region to form the silicide layer over only the periphery region.

14. A method, comprising:
preparing a semiconductor substrate having a pixel region and a periphery region;
forming a gate electrode over each of the pixel region and the periphery region;
coating a poly oxide layer over the semiconductor substrate;
depositing a linear nitride layer over the poly oxide layer;
forming a silicide barrier layer over the poly oxide layer;
removing the poly oxide layer, the linear nitride layer, and the silicide barrier layer from the periphery region;
forming a silicide layer over only the periphery region; and
removing the silicide barrier layer remaining over the pixel region.

15. The method of claim 14, further comprising:
forming an insulating layer over the semiconductor substrate;
selectively etching the insulating layer to form a hole in each of the pixel region and the periphery region; and
filling each hole with metal to form contacts.

16. The method of claim 15, wherein a thickness of the linear nitride layer ranges from approximately 300 Å to approximately 500 Å.

17. The method of claim 16, wherein the silicide barrier layer comprises plasma-enhanced tetra-ethyl-ortho-silicate (PETEOS).

18. The method of claim 17, wherein the insulating layer comprises phosphorus silicate glass (PSG).
